(19) United States
(12) Patent Application Publication
(10) Pub. No.: US 2025/0331120 A1
(43) Pub. Date: Oct. 23, 2025

(54) DATA STORAGE SYSTEMS AND CHASSIS ASSEMBLIES WITH RACK ADAPTERS IN DATA STORAGE SYSTEMS

(71) Applicant: Sanmina Corporation, San Jose, CA (US)

(72) Inventors: Odie Banks Killen, Jr., Colorado Springs, CO (US); Kent Murphy, Colorado Springs, CO (US); Qilu He, Colorado Springs, CO (US)

(21) Appl. No.: 19/184,540

(22) Filed: Apr. 21, 2025

Related U.S. Application Data
(60) Provisional application No. 63/637,327, filed on Apr. 22, 2024.

(51) Int. Cl. H05K 7/14; H05K 5/03; H05K 7/18

(52) U.S. Cl. CPC H05K 7/1489; H05K 5/03; H05K 7/1491; H05K 7/183

(57) ABSTRACT

Data storage systems may include a chassis and an adapter assembly including a first side coupled to the chassis. The first side may form at least one channel between an outer panel of the first side and the chassis. A second side of the adapter assembly may be coupled to the chassis. Methods of making data storage systems may include obtaining a chassis, and coupling a first side of an adapter assembly to the chassis. The first side can form at least one channel located between an outer panel of the first side and the chassis. Other aspects, embodiments, and features are also included.

### PRIORITY CLAIM

This application claims priority to and the benefit of provisional patent application No. 63/637,327 filed in the U.S. Patent and Trademark Office on Apr. 22, 2024, the entire content of which is incorporated herein by reference as if fully set forth below in its entirety and for all applicable purposes.

### TECHNICAL FIELD

The technology discussed below relates generally to data storage systems, and more specifically to chassis adapters for data storage systems.

### BACKGROUND

Computer and network systems such as data storage systems (e.g., server systems, cloud storage systems, just a bunch of drives/disks (JBOD), just a bunch of flash (JBOF), personal computers, and workstations) typically include data storage devices for storing and retrieving data. These data storage devices can include hard disk drives (HDDs), solid state drives (SSDs), etc., that include both rotating and solid state data storage elements.

As computer systems and networks grow in numbers and capability, there is a need for ever increasing storage capacity. Data centers, cloud computing facilities, and other at-scale data processing systems have further increased the need for digital data storage systems capable of transferring and holding immense amounts of data. Data centers can house large quantities of data storage systems stored in various rack-mounted and high-density storage configurations.

Features and systems that can improve the operation and function of data storage systems are generally desirable.

### BRIEF SUMMARY OF SOME EXAMPLES

The following summarizes some aspects of the present disclosure to provide a basic understanding of the discussed technology. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later.

Various examples and implementations of the present disclosure facilitate improvements to the operation and function of data storage systems. According to at least one example, data storage systems may include a chassis and an adapter assembly including a first side coupled to the chassis. The first side of the adapter assembly can form at least one channel between an outer panel of the first side and the chassis.

One or more additional examples include data storage systems with a chassis, a first side of an adapter assembly coupled to the chassis, and a second side of the adapter assembly coupled to the chassis. The first side of the adapter assembly can form at least one channel between an outer panel of the first side and the chassis.

Yet additional aspects of the present disclosure include methods of making data storage systems. According to at least one implementation, such methods may include obtaining a chassis and coupling a first side of an adapter assembly to the chassis. The first side of the adapter assembly can form at least one channel between an outer panel of the first side and the chassis.

Other aspects, features, and embodiments associated with the present disclosure will become apparent to those of ordinary skill in the art upon reviewing the following description in conjunction with the accompanying figures.

### DRAWINGS

FIG. 1 is a rear isometric view of a data storage system according to at least one embodiment.

FIG. 2 is a front elevation view of two data storage systems positioned in a rack.

FIG. 3 is a rear isometric view of a data storage system according to at least one embodiment.

FIG. 4 is a rear elevation view of a data storage system positioned in a rack according to at least one example.

FIG. 5 is a rear isometric view showing two data storage systems positioned in a rack, with one data storage system extended from the rack on rails.

FIG. 6 is a side elevation view of a first side of a data storage system according to at least one embodiment.

FIG. 7 is a front isometric view of a data storage system according to at least one embodiment.

FIG. 8 is a top plan view of a data storage system according to at least one embodiment.

FIG. 9 is a front isometric view of a rack with data storage systems of the present disclosure coupled thereto.

FIG. 10 is a flow diagram depicting at least one example of a method of making a data storage system.

### DETAILED DESCRIPTION

The description set forth below in connection with the appended drawings is intended as a description of various configurations and is not intended to represent the only configurations in which the concepts and features described herein may be practiced. The following description includes specific details for the purpose of providing a thorough understanding of various concepts. However, it will be apparent to those skilled in the art that these concepts may be practiced without these specific details. In some instances, well known circuits, structures, techniques and components are shown in block diagram form to avoid obscuring the described concepts and features.

The illustrations presented herein are, in some instances, not actual views of any particular data storage system, data storage assembly, or adapter assembly, but are merely representations which are employed to describe the present disclosure. Additionally, elements common between figures may retain the same numerical designation.

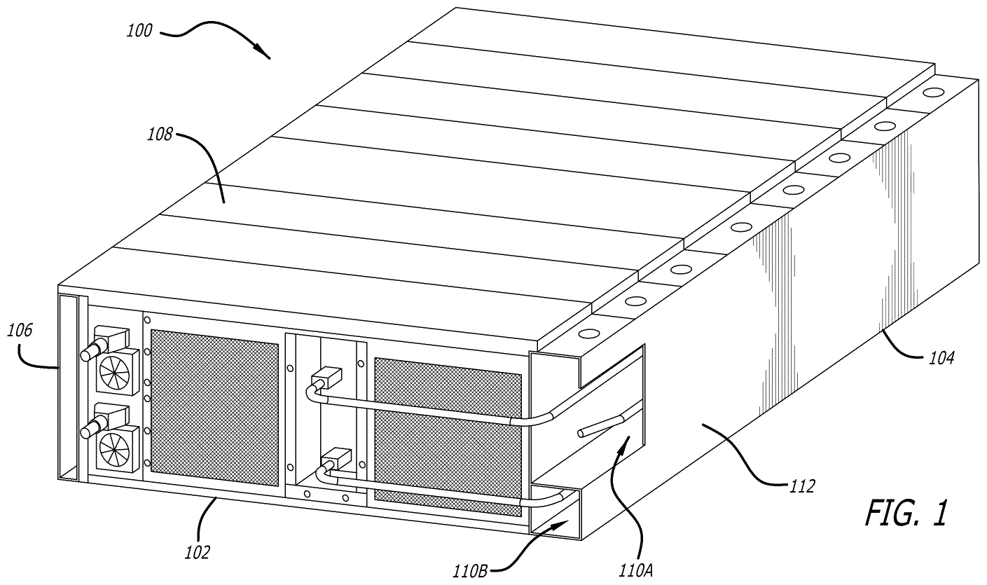

Aspects of the present disclosure relate to data storage systems, such as general I/O (input/output) modules, server modules, JBOD (Just a Bunch Of Drives) and JBOF (Just a Bunch Of Flash), by way of example. Example data storage systems may be configured for storage in various rack-mounted and high-density storage configurations. Example data storage systems may include many storage media devices with conventional I/O modules to facilitate a JBOD/JBOF configuration. Referring to FIG. 1, an isometric view of a data storage system 100 is depicted according to at least one embodiment. The data storage system 100 may include a chassis 102, which provides a housing or enclosure for various components. In some instances, a chassis 102 may have a particular width, while a rack mounting assembly may employ a wider width than a particular chassis 102. For example, the Open Compute Project (OCP) specifies a 21-inch chassis for use in a OCP Rack. The OCP rack specifies an Open Rack Unit (ORU) that is slightly larger than the standard 19-inch rack unit (RU) defined by the EIA-310 industry standard. Accordingly, a chassis designed for the standard 19-inch rack cannot be used in an OCP-style rack because of the different sizes. Those of ordinary skill in the art will recognize that the actual measurements may vary for different applications, while the principles of the present application will still apply.

According to one or more aspects, an adapter assembly is provided to enable the chassis 102 (e.g., a 19-inch wide rack chassis) to be used with a wider rack (e.g., a 21-inch wide rack). For example, an adapter assembly may enable any existing EIA-310-compliant chassis to be converted to a size corresponding to an OCP chassis for OCP applications. The adapter assembly includes at least a first side 104. In some embodiments, such as that shown in FIG. 1, the adapter assembly may further include a second side 106. Further, some embodiments may include a lid 108 coupled between the first side 104 and the second side 106. In embodiments with just the first side 104, the width of the first side 104 is equal to the width to be adapted. In embodiments with both the first side 104 and the second side 106, the combination of the widths for each side are equal to the width to be adapted. In some implementations, the first side 104 may also be referred to as the wide side, and the second side 106 may also be referred to as the short side, where the wide side is wider than the short side. In yet other embodiments, the first side 104 and the second side 106 may be equal widths.

The first side 104 may include channel 110 formed between an outer panel 112 and the chassis 102. In the example shown, the first side 104 is configured with two channels identified as 110A and 110B. It should be understood that the number of channels may be determined based on design preference, while the total number may be one or more channels. Each channel 110 may be formed as a space between the outer panel 112 and the chassis 102. As used herein, the channel being between the outer panel 112 and the chassis 102 includes an inner wall being formed by either an inner panel of the first side 104 or a side surface of the chassis, according to various embodiments. Additionally, one or more embodiments of the first side 104 of the adapter assembly can include structural support on the outer panel 112 for slide rail mounting.

The second side 106 may be utilized for structural support, mechanical integration and slide rail mounting. In some embodiments, the second side 106 includes mechanically coupled surfaces for lids 108. For example, the second side 106 may include a hinge mechanism to mechanically couple a lid 108.

In some examples, the adapter assembly may be utilized to adapt to the rack unit height difference and differences in mounting hole locations. For example, one ORU is 48 mm tall, while a standard Rack Unit (e.g., regular U) is 44.45 mm tall. Through use of an adapted assembly of the present disclosure, the additional height may be utilized to enable novel or unique lid structures not previously available in the conventional rack mount product offering.

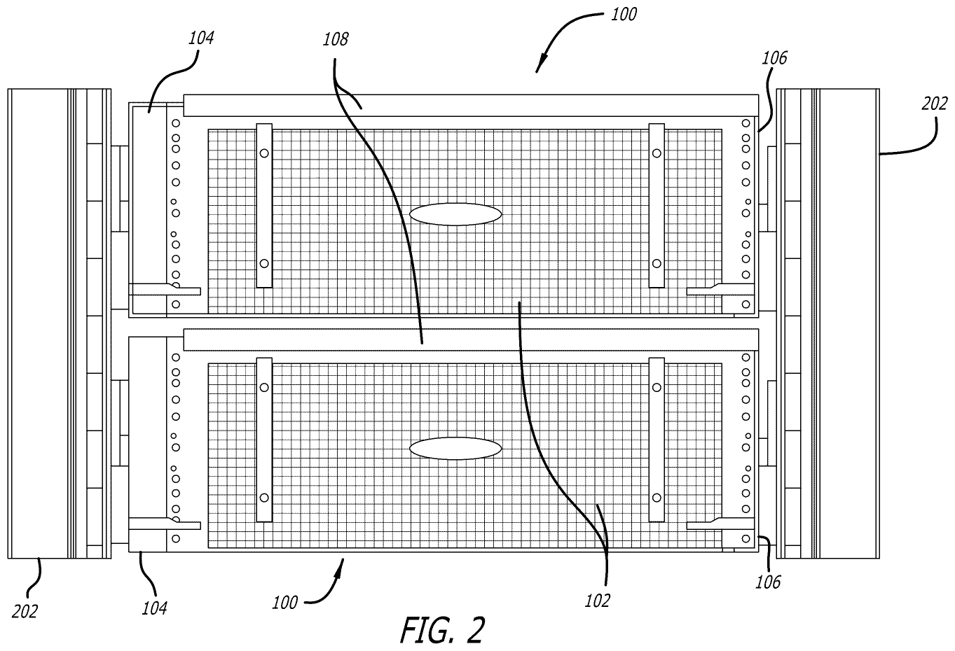

FIG. 2 is a front elevation view of two data storage systems 100 positioned in a rack 202. The depicted rack 202 illustrates conventional 4U chassis 102, populated with 102 HDDs in a 21-inch rack using the adapter assembly of the present disclosure according to at least one example with a first side 104 and a second side 106 coupled to each chassis 102.

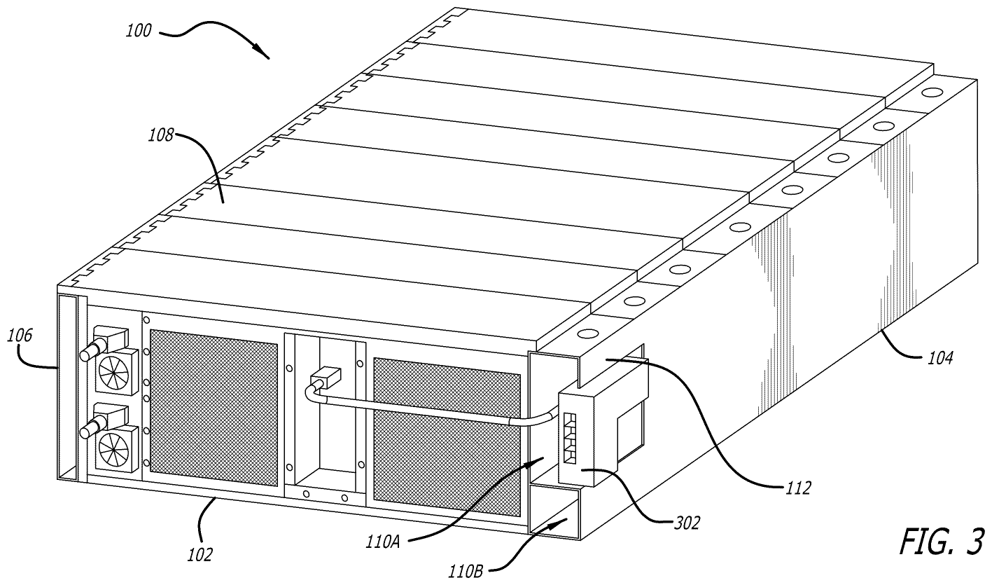

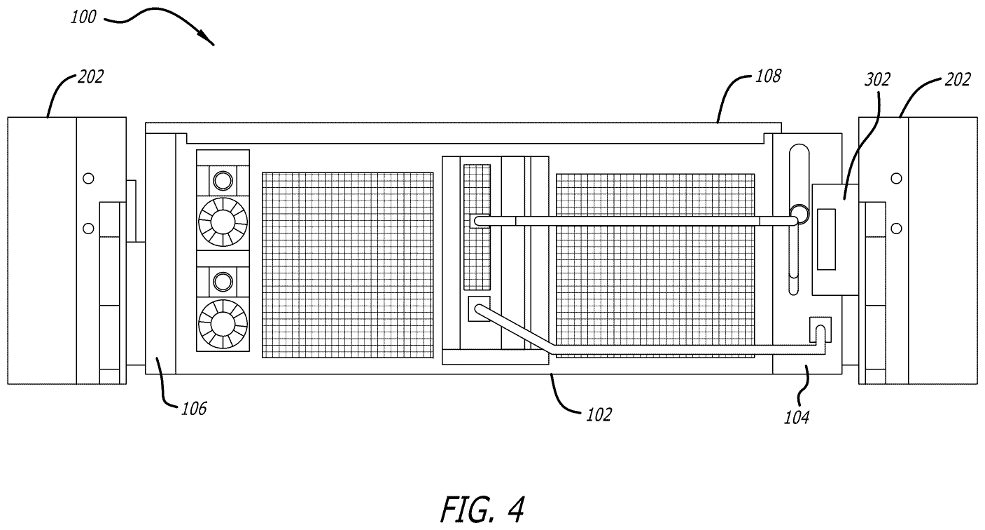

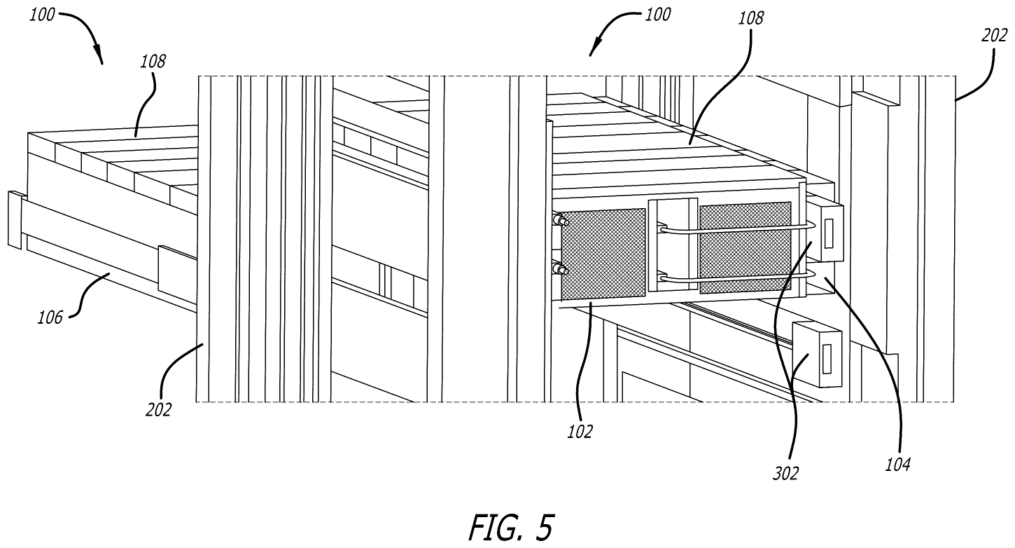

According to one or more aspects of the present disclosure, the first side 104 is configured to facilitate internal cable management within the first side 104. For example, cables can be pulled into the channel 110 of the first side 104, and can be directed out of either of the front or back of the channel 110 of the first side 104. FIG. 3 shows another isometric view of an embodiment of a data storage system 100 including a bulkhead 302 positioned at least partially within a channel 110. Similarly, FIG. 4 is an elevation view of a data storage system 100 positioned in a rack 202 according to at least one example with a bulkhead 302, and FIG. 5 is an isometric view showing two data storage systems 100 positioned in a rack 202, with one data storage system extended from the rack 202 on rails according to at least one embodiment.

Another bulkhead (not shown) may be on the other longitudinal side of the first side 104. The cable bulkheads 302 can be implemented to support any type of cable interface. The bulkheads 302 can facilitate transitions between the front of the first side 104 and the rear of the first side 104. The bulkhead 302 may affix the cables to the rack, as shown in FIG. 5, which may eliminate any rear-mounted cable management assembly (CMA) solutions that conventionally add additional depth to the unit. The bulkhead 302 can also be affixed in the chassis 102 or may be mounted to a rail kit, according to various implementations.

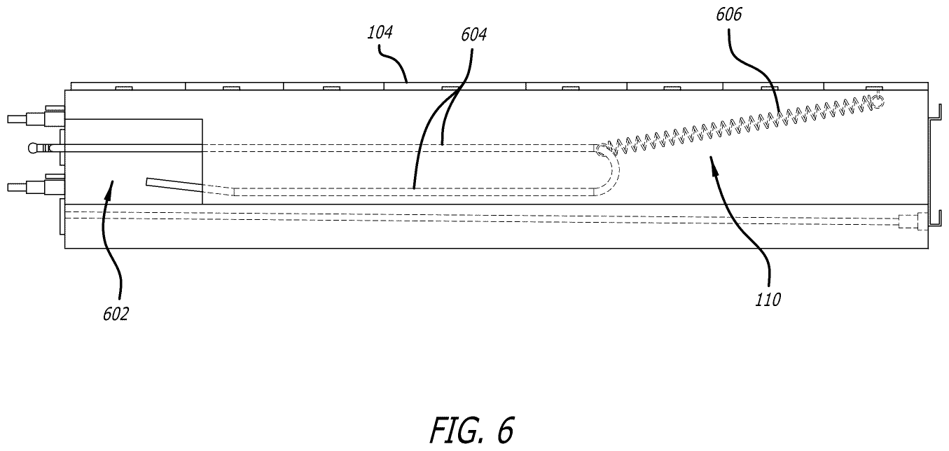

FIG. 6 is a side elevation view of the first side 104 illustrating internal cable management utilizing a CMA within a channel 110 according to at least one example. In the depicted example, the first side 104 may include a bulkhead positioned about at the area indicated by arrow 602, as well as cables 604 and a CMA structure 606. The internal CMA may enable the bulkhead 602 to be affixed to the rack while the chassis 102 is able to translate within the rack. That is, as the chassis 102 is moved, such as the lower chassis in FIG. 5, the bulkhead 602 (or bulkhead 302 in FIG. 5) can remain affixed to the rack, the chassis can translate inward and outward relative to the rack, and the CMA structure 606 can facilitate extension and retraction of the cables 604 within the channel 110 as the chassis is repositioned relative to the rack.

The cables 604 may be any type of cables used in a data storage system 100. In the example shown in FIG. 6, the top cable 604 is depicted as a Serial-Attached SCSI (SAS) cable coupled to a bulkhead 602, and the bottom cable 604 is depicted as an ethernet cable. The bottom cable 604 depicts an example of a static CMA structure, while the top cable 604 depicts an example of a dynamic CMA structure, according to one or more examples of the first side 104.

The CMA structure 606 is depicted as a spring, but any known structure may be employed as the CMA structure 606. By way of example, the CMA structure 606 may be one or more of a chain style link, a spring, a belt, a pulley, a hinge, or other known structures.

By facilitating cable management in the first side 104, the adapter assembly may enable the relocation of rack mount interfaces between the front and the back of the chassis 102. That is, cables can be affixed in either the front or the rear of the chassis, such that rear-connected cables can be connected in the front and vice versa. Such features facilitate flexibility as to where cables can connect, and can increase the number of rack configurations that can be supported by the adapter assembly.

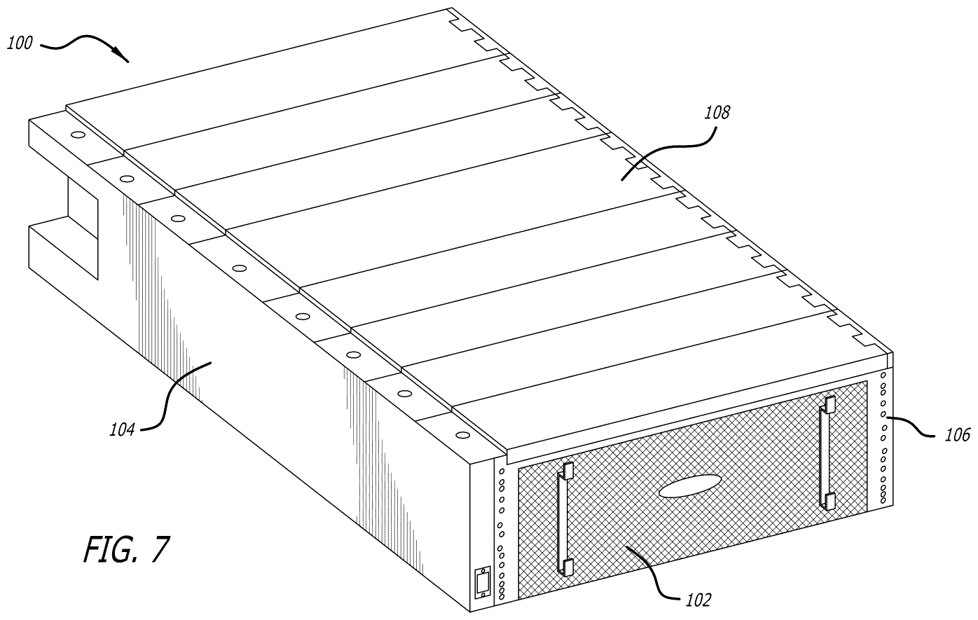

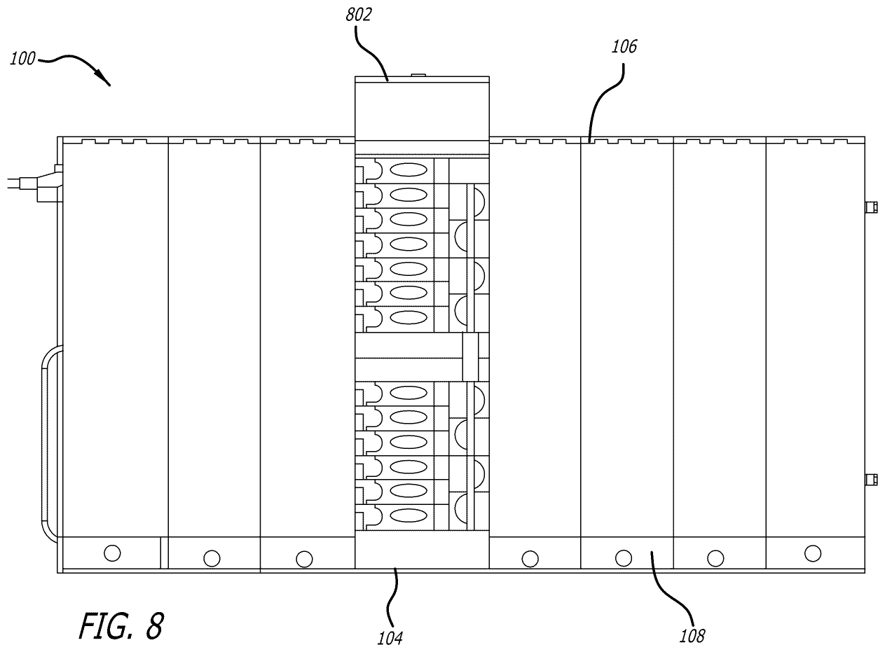

According to additional features of the present disclosure, the adapter assembly utilizing both a first side 104 and a second side 106 may employ a single or multi-piece lid 108 depicted in FIG. 7. The multi-piece lid 108 showing in FIG. 7 is mechanically coupled on the second side 106 using hinges or other applicable mechanical features to facilitate access to a single row of drives within the chassis 102. FIG. 8 is a top plan view of the data storage system 100 showing one panel 802 of a multi-piece lid 108 opened for access to a single row of drives within the chassis 102. As shown in FIG. 8, the lid 108 may be latched on the first side 104, and hinged on the second side 106.

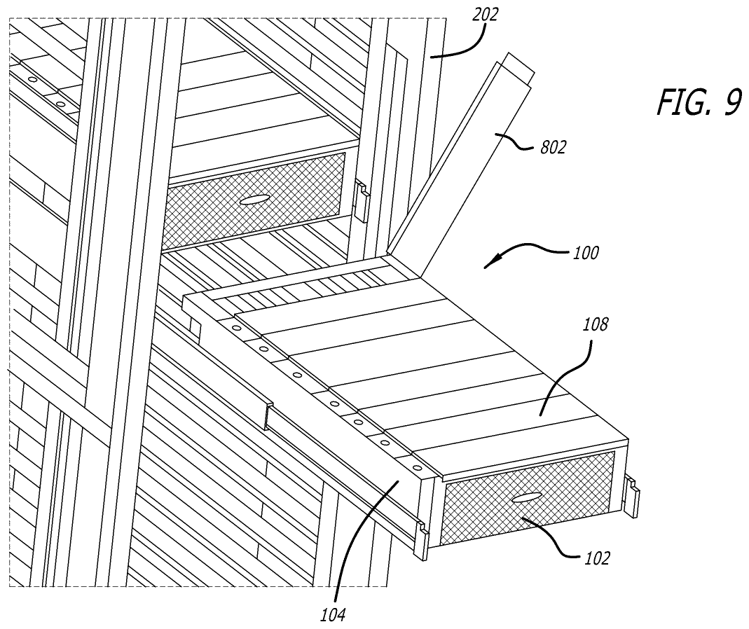

FIG. 9 is an isometric view showing a data storage system 100 coupled to a rack 202 with the data storage system 100 extended from the rack 202. As depicted, a single panel 802 of the lid 108 is opened for access to a single drive row within the chassis 102. At least one benefit of enabling access to a single drive row within the chassis 102 may include the ability to ensure sufficient airflow across the other drive rows while accessing one drive row. That is, only opening the panel above a single row of serviced drives can restrict the airflow leaking across all other drives and keep the airflow moving from the cold aisle to the hot aisle. The single panel ensures that the non-serviced drives have sufficient airflow and remain properly cooled and fully functional as compared to removing one lid above all drives, as is typically done in conventional chassis designs.

In some implementations, a lid 108 can employ different configurations to obtain different features. Different lids 108, including single or multi-piece lids 108, may also accommodate for differences in heights between the chassis 102 and the rack configuration.

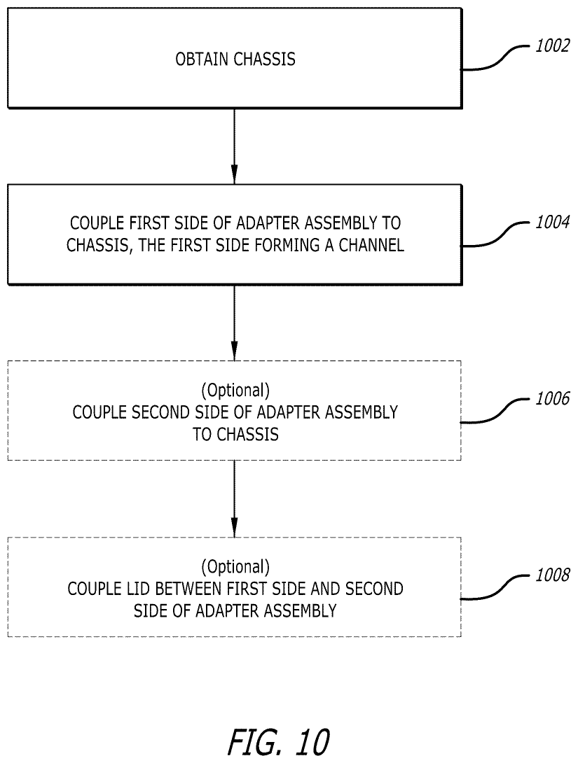

Additional aspects of the present disclosure include methods of making a data storage system. FIG. 10 is a flow diagram depicting at least one example of a method of making a data storage system. With reference to FIGS. 1-10, an example of an implementation of a method may include obtaining a chassis 102 at step 1002. The chassis 102 may be configured for housing various components, such as components for a general I/O module, server module, storage media, etc.

At 1004, a first side 104 of an adapter assembly is coupled to the chassis 102. The first side 104 forms at least one channel 110 between an outer panel 112 of the first side 104 and the chassis 102. As described herein, the channel being between the outer panel 112 and the chassis 102 includes embodiments with an inner wall of the channel 110 formed by either an inner panel of the first side 104 or a side surface of the chassis.

In one or more embodiments, a CMA structure 606 is positioned within the channel 110 of the first side 104. As described above, the CMA structure 606 may be a static CMA structure or a dynamic CMA structure. As also described above, the CMA structure 606 positioned within the channel 110 may include any known structure including, but not limited to, a chain style link, mechanical chain link, a spring, a belt, a pulley, a hinge, or other known structures.

In at least some implementations, a bulkhead 302, 602 may be positioned within at least a portion of the channel 110.

At 1006, some implementations may optionally include coupling a second side 106 of the adapter assembly to the chassis 102. The second side 106 may be coupled to a portion of the chassis 102 opposite from the portion of the chassis 102 where the first side 104 of the adapter assembly is coupled.

At 1008, with a second side 106 coupled to the chassis 102, a lid 108 may be coupled between the first side 104 and the second side 106 of the adapter assembly. In various embodiments, the lid 108 may be configured as a single-piece or a multi-piece lid 108 mechanically coupled on the second side 106. In some examples, a multi-piece lid 108 may facilitate access to a single row of drives within the chassis 102.

While the above discussed aspects, arrangements, and embodiments are discussed with specific details and particularity, one or more of the components, steps, features and/or functions illustrated in FIGS. 1, 2, 3, 4, 5, 6, 7, 8, 9, and/or 10 may be rearranged and/or combined into a single component, step, feature or function or embodied in several components, steps, or functions. Additional elements, components, steps, and/or functions may also be added or not utilized without departing from the present disclosure. The apparatus, devices and/or components illustrated in FIGS. 1, 2, 3, 4, 5, 6, 8, and/or 9 may be configured to perform or employ one or more of the methods, features, parameters, and/or steps described with reference to FIG. 10.

While features of the present disclosure may have been discussed relative to certain embodiments and figures, all embodiments of the present disclosure can include one or more of the advantageous features discussed herein. In other words, while one or more embodiments may have been discussed as having certain advantageous features, one or more of such features may also be used in accordance with any of the various embodiments discussed herein. In similar fashion, while exemplary embodiments may have been discussed herein as device, system, or method embodiments, it should be understood that such exemplary embodiments can be implemented in various devices, systems, and methods.

Also, it is noted that at least some implementations have been described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features associated with the examples described herein and shown in the accompanying drawings can be implemented in different examples and implementations without departing from the scope of the present disclosure. Therefore, although certain specific constructions and arrangements have been described and shown in the accompanying drawings, such embodiments are merely illustrative and not restrictive of the scope of the disclosure, since various other additions and modifications to, and deletions from, the described embodiments will be apparent to one of ordinary skill in the art. Thus, the scope of the disclosure is only determined by the literal language, and legal equivalents, of the claims which follow.

What is claimed is:

1. A data storage system, comprising:
a chassis; and
an adapter assembly including a first side coupled to the chassis, wherein the first side forms at least one channel between an outer panel of the first side and the chassis.

2. The data storage system of claim 1, wherein the first side of the adapter assembly comprises a cable management assembly positioned at least in part within the at least one channel of the first side of the adapter assembly.

3. The data storage system of claim 2, wherein the cable management assembly comprises at least one of a chain style link, mechanical chain link, a spring, a belt, a pulley, or a hinge.

4. The data storage system of claim 1, wherein the adapter assembly further comprises a second side coupled to the chassis on a side opposite from the first side.

5. The data storage system of claim 4, further comprising a lid coupled between the first side and the second side of the adapter assembly.

6. The data storage system of claim 5, wherein the lid comprises a multi-piece lid configured to facilitate access to a single row of drives within the chassis.

7. The data storage system of claim 1, further comprising at least one bulkhead positioned at least partially within the at least one channel.

8. A data storage system, comprising:
a chassis;
a first side of an adapter assembly coupled to the chassis, wherein the first side forms at least one channel with an outer panel of the first side; and
a second side of the adapter assembly coupled to the chassis.

9. The data storage system of claim 8, further comprising:
a lid coupled between the first side of the adapter assembly and the second side of the adapter assembly.

10. The data storage system of claim 9, wherein:
the lid coupled between the first side of the adapter assembly and the second side of the adapter assembly comprises a multi-piece lid configured to facilitate access to a single row of drives within the chassis.

11. The data storage system of claim 9, wherein the lid is mechanically coupled to the second side of the adapter assembly.

12. The data storage system of claim 8, wherein the first side of the adapter assembly comprises a cable management assembly positioned at least in part within the at least one channel of the first side of the adapter assembly.

13. The data storage system of claim 12, wherein the cable management assembly comprises at least one of a chain style link, mechanical chain link, a spring, a belt, a pulley, or a hinge.

14. The data storage system of claim 8, further comprising a first slide rail mount coupled to the first side of the adapter assembly and a second slide rail mount coupled to the second side of the adapter assembly.

15. A method of making a data storage system, comprising:
obtaining a chassis; and
coupling a first side of an adapter assembly to the chassis, the first side forming at least one channel located between an outer panel of the first side and the chassis.

16. The method of claim 15, comprising:
coupling a second side of the adapter assembly to the chassis, the second side coupled to a portion of the chassis opposite from a portion of the chassis where the first side of the adapter assembly is coupled.

17. The method of claim 16, further comprising:
coupling a lid between the first side of the adapter assembly and the second side of the adapter assembly.

18. The method of claim 15, wherein coupling the first side of the adapter assembly to the chassis comprises:
coupling the first side of the adapter assembly with a cable management assembly positioned at least in part within the at least one channel of the first side of the adapter assembly.

19. The method of claim 15, further comprising:
positioning at least one bulkhead within at least a portion of the at least one channel.

20. The method of claim 15, wherein coupling the first side of the adapter assembly to the chassis, the first side forming at least one channel located between an outer panel of the first side and the chassis comprises:
coupling the first side of the adapter assembly to the chassis, the first side forming a plurality of channels located between an outer panel of the first side and the chassis.
